(19) United States
(12) Patent Application Publication
(10) Pub. No.: US 2026/0118430 A1
(43) Pub. Date: Apr. 30, 2026

(54) READING BACK THE SWITCHING STATES OF TWO SWITCHES VIA A MICROCONTROLLER

(71) Applicant: WAGO Verwaltungsgesellschaft mbH, Minden (DE)

(72) Inventors: Torsten MEYER, Pennigsehl (DE); Christian VOSS, Minden (DE); Jonathan HAMM, Porta Westfalica (DE)

(73) Assignee: WAGO Verwaltungsgesellschaft mbH, Minden (DE)

(21) Appl. No.: 19/433,141

(22) Filed: Dec. 26, 2025

Related U.S. Application Data
(63) Continuation of application No. PCT/EP2024/066493, filed on Jun. 13, 2024.

(30) Foreign Application Priority Data
Jul. 5, 2023 (DE) 10 2023 117 731.1

(51) Int. Cl. G01R 31/327

(52) U.S. Cl. CPC G01R 31/3277

(57) ABSTRACT

Provided is an apparatus comprising a microcontroller, a first switch, a second switch, and an output. The first switch and the second switch are connected in series and control a current to be output at the output. The apparatus is configured to open the first switch and the second switch as part of a test routine. A first input of the microcontroller is connected to a first terminal of the first switch via a first resistor. A second input of the microcontroller is connected to a second terminal of the first switch via a second resistor. When the first switch is open, there is no current flow between the first terminal and the second terminal of the first switch. The microcontroller is configured to detect the voltages at the first and second inputs when switches are closed and to take them into account as part of the test routine.

This nonprovisional application is a continuation of International Application No. PCT/EP2024/066493, which was filed on June 13, 2024, and which claims priority to German Patent Application No. 102023117 731.1, which was filed in Germany on July 5, 2023, and which are both herein incorporated by reference.

### BACKGROUND OF THE INVENTION

### Field of the Invention

The present description relates to a determination of switch states. In particular, the present description relates to checking the switching capability of switches by a microcontroller.

### Description of the Background Art

To avoid that the failure of a switch prevents the de-energization of a load connected to an output, two independently switchable switches may be arranged in series between a pole of the power supply and the output, so that the load can be de-energized as long as at least one of the switches is functional. Although the failure of one switch may hence be harmless, it is advantageous to regularly check both switches with respect to their function so that the failed switch or the circuit comprising the failed switch can be replaced before the second switch fails as well.

### SUMMARY OF THE INVENTION

It is therefore an object of the present invention to provide an apparatus that comprises a microcontroller, a first switch, a second switch and an output, wherein the first switch and the second switch are connected in series and configured to control a current to be output at the output. The apparatus according to the invention is configured to test whether the first switch and the second switch function, as part of an automatically performed test routine, wherein the apparatus is further configured to open the first switch and the second switch as part of the test routine. Furthermore, a first input of the microcontroller is connected via a first resistor to a first terminal of the first switch, and a second input of the microcontroller is connected via a second resistor to a second terminal of the first switch, wherein no current flows between the first terminal of the first switch and the second terminal of the first switch when the first switch is open. The microcontroller is configured to detect the voltages at the first and second inputs when the first and second switches are closed and to take them into account as part of the test routine. By taking into account the voltages at the first and second inputs when the first and second switches are closed, influences on the voltages at the inputs during the test routine, arising from component tolerances or certain circuit layouts, can be compensated for during evaluation by the microcontroller.

In this regard, the term "microcontroller", can be understood, in particular, as referring to an integrated circuit with a processor. Furthermore, the term "processor", can be understood, in particular, as referring to an electronic circuit configured to execute instructions from a predetermined set of instructions. The sequence of instructions to be executed may be derived from a program stored in memory assigned to the processor, which specifies the functionality provided by the processor. For example, a program comprising the test routine may be stored in the memory allocated to the processor, which causes the microcontroller to execute the test routine cyclically or on demand.

Furthermore, the term "switch", can be, in particular, as referring to an electronic switch which, depending on the state of the switch, electrically connects two switch terminals or disconnects the switch terminals from each other. Furthermore, the terms "input" and "output", can be understood, in particular, as referring to electrical connections through which a voltage and/or a current can be input or output. The voltage and/or current input into a circuit are determined by circuit elements outside the circuit, whereas the voltage and/or current output by a circuit are determined by the circuit.

The first input of the microcontroller may be connected to ground via a third resistor. The second input of the microcontroller may be connected to ground via a fourth resistor.

The first input of the microcontroller may be provided with a first analog-to-digital converter. The second input of the microcontroller may be provided with a second analog-to-digital converter.

Alternatively, the first input of the microcontroller may be connected to the first terminal of the first switch via a first analog-to-digital converter and the first resistor, and the second input of the microcontroller may be connected to the second terminal of the first switch via a second analog-to-digital converter and the second resistor.

The second input of the microcontroller may be connected to a first terminal of the second switch via the second resistor.

The test routine may comprise opening the second switch and monitoring a voltage drop at the second input and opening the first switch and monitoring a voltage drop at the first input.

In this regard, the term "voltage drop", can be understood, in particular, as referring to a reduction of the absolute value of the difference between the potential at the respective input and the ground potential, i.e., the potential at the respective input approaches ground potential.

The taking into account as part of the test routine may comprise shifting a target voltage range with respect to a voltage difference between the first input and the second input or correcting the voltage difference based on the detected voltages.

A third input of the microcontroller may be connected to a second terminal of the second switch via a third resistor.

The microcontroller may be configured to detect the voltage at the third input when the first and second switches are closed and to take it into account as part of the test routine.

The third input of the microcontroller may be provided with a third analog-to-digital converter.

The first switch may be a first semiconductor switch controlled by the microcontroller. The second switch may be a second semiconductor switch controlled by the microcontroller.

Notably, all steps carried out when using the apparatus according to the invention may be features of a corresponding method.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a schematic representation of an apparatus according to an example;

FIG. 2 shows a schematic representation of the voltages at the inputs of the microcontroller before and during the test routine;

FIGS. 3, 4, 5, and 6 illustrate two ways of taking into account the voltages at the first and second inputs when the first and second switches are closed as part of the test routine;

FIG. 7 illustrates a first modification of the example shown in FIG. 1;

FIG. 8 illustrates a second modification of the example shown in FIG. 1; and

FIG. 9 illustrates a modification of the example shown in FIG. 8.

### DETAILED DESCRIPTION

The apparatus 10 schematically shown in FIG. 1 comprises a microcontroller 12, two switches 14 and 16, and an output 18. The switches 14 and 16 are connected in series and connect the output 20 to a power supply. When the switches 14 and 16 are closed, a voltage V+ (alternatively V-) is output at the output 20. The magnitude of the voltage V+ (alternatively V-) may be many times higher than the supply voltage of the microcontroller 12. For example, the voltage V+ may be greater than 6 V (e.g. greater than 12 V, greater than 18 V, greater than 24 V or around 31.2 V) and the supply voltage of the microcontroller 12 may be less than 2 V.

When one or both switches 14 and 16 are open, the output 18 is connected to ground with high impedance. If a load is connected to output 18, it is supplied with energy or activated by closing the switches 14 and 16 and deactivated by opening the switches 14 and 16. To test the functionality of switches 14 and 16 (at regular intervals or in response to a request), the microcontroller 12 opens switch 14 in a first test phase T1 (following a normal operating phase N) and switch 16 in a second test phase T2.

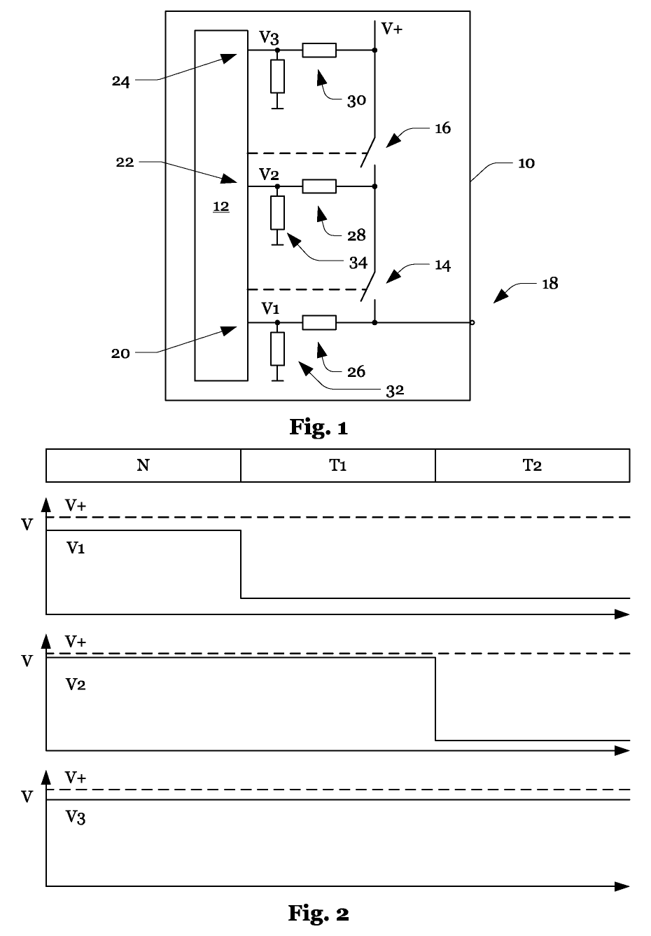

As shown in FIG. 2, the voltage V3 applied to input 24 does not change when switches 14 and 16 are opened. The voltage V3 may therefore be used to monitor the voltage V+ during the test phases T1 and T2. If the voltage V+ is sufficiently stable or if the voltage V+ is monitored in another way, monitoring the voltage V+ may be omitted. Unlike the voltage V3 applied to input 24, the voltage V2 applied to input 22 drops when switch 14 is opened. Furthermore, the voltage V1 applied to input 20 drops when switch 14 or switch 16 is opened, since inputs 20 and 22 are connected to ground via resistors 32 and 34 respectively.

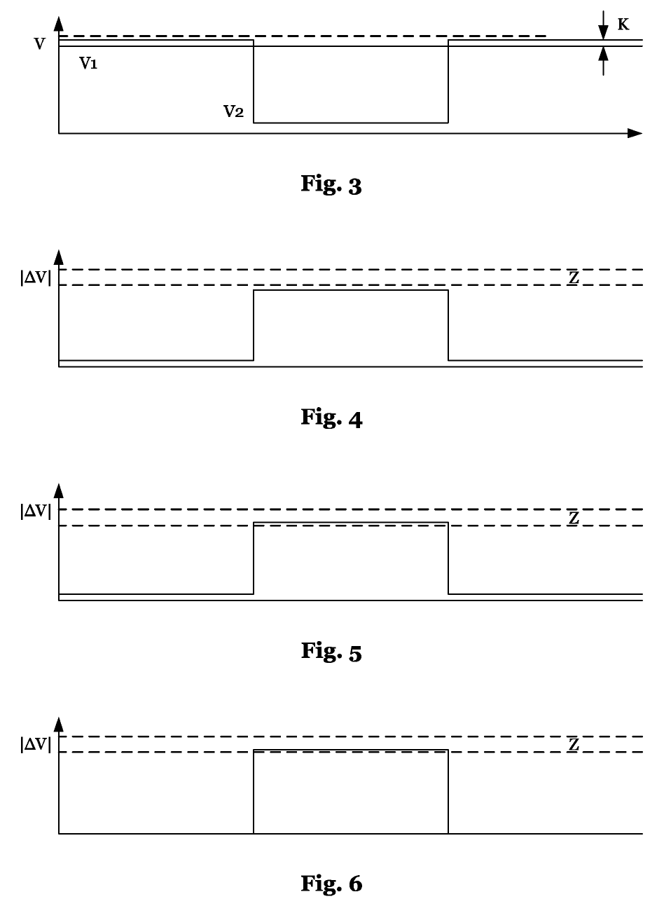

The drop in voltages V1 and V2 may be detected by the microcontroller 12 and used to check whether the switches 14 and 16 are functioning correctly. In particular, detecting the voltage ΔV=V2-V1 between input 20 and input 22 when switch 14 is open allows verifying whether opening switch 14 allows de-energizing a load connected to output 18. In order to take into account the influence of the resistors 26 and 28 and, in the case of identical resistors 26 and 28, in particular, their tolerances, a correction value K= ΔV(N) may be determined from the values of the voltages V1 and V2 when the switches 14 and 16 are closed, as shown in FIG. 3.

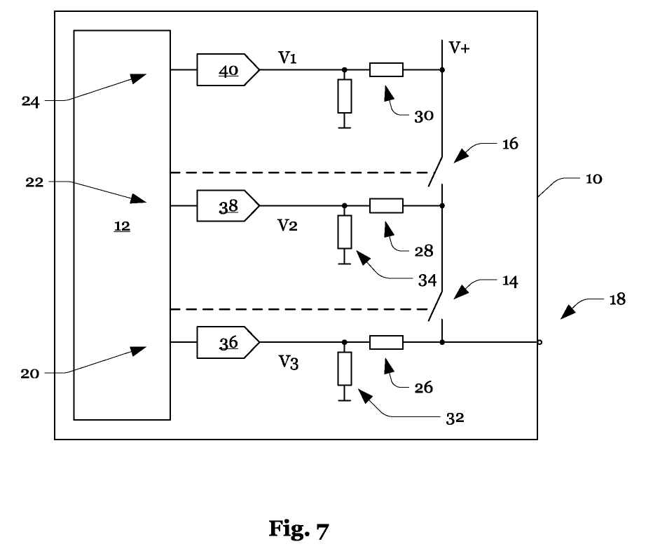

While, as shown in FIG. 4, the absolute value of the difference ΔV=V2-V1 when switch 14 is open and without taking the correction value K into account would lie outside a target voltage range Z, by shifting the target voltage range Z by K, as shown in FIG. 5, or by taking the correction value K into account when determining the difference ΔV, as shown in FIG. 6, it can be achieved that the absolute value of the difference ΔV when switch 14 is open lies within the target voltage range Z. Furthermore, taking the correction value K into account can also be advantageous if the difference ΔV when switch 14 is open and without taking the correction value K into account would lie within the target voltage range Z, since the time required to test switch 14 can be reduced if the test phase T1 ends when the target voltage range Z is reached and then the test phase T2 can be started (immediately).

The same check may be carried out with regard to switch 16 by recording voltage V2 applied to input 22 and voltage V3 applied to input 24 and evaluating them while taking into account a correction value. If the switching capability of both switches 14 and 16 is confirmed, normal operation of the microcontroller 12 may be resumed. If the switching capability of only one or none of the switches 14 and 16 is confirmed, the microcontroller 12 may signal this to a system comprising the apparatus 10. The system may then forward the error message, process it, and/or switch to a safe state.

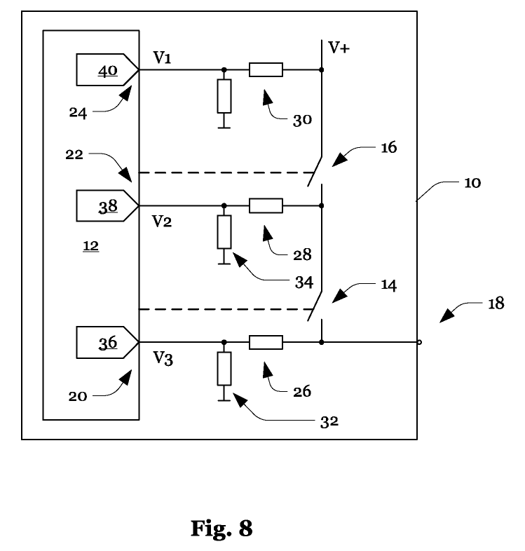

As shown in FIG. 7, the inputs 20, 22, and 24 of the microcontroller 12 may be connected to the terminals of the switches 14 and 16 via analog-to-digital converters 36, 38, and 40. As shown in FIG. 8, the inputs 20, 22 and 24 of the microcontroller 12 may be provided with analog-to-digital converters 36, 38 and 40. The provision of analog-to-digital converters 36, 38 and 40, as well as the provision of resistors 26, 28 and 30, may, in particular, be appropriate if the voltage V+ is higher than the logic voltage of the microcontroller 12.

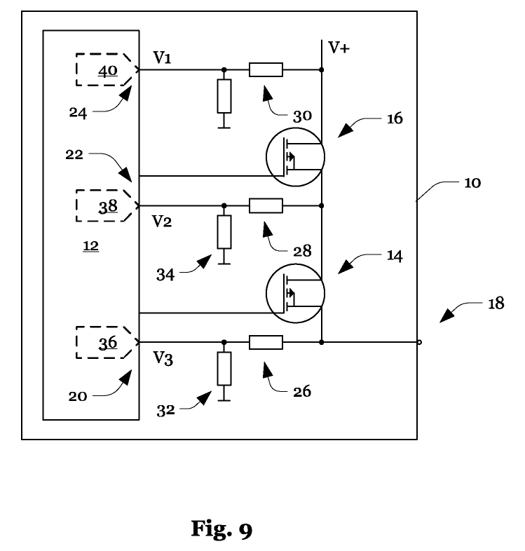

Furthermore, the switches 14 and 16 may be semiconductor switches which are controlled by the microcontroller 12, as shown exemplarily in FIG. 9.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An apparatus comprising:
a microcontroller;
a first switch;
a second switch; and
an output,
wherein the first switch and the second switch are connected in series and configured to control a current to be output at the output,
wherein the apparatus is configured to test whether the first switch and the second switch function as part of an automatically performed test routine,
wherein the apparatus is further configured to open the first switch and the second switch as part of the test routine,
wherein a first input of the microcontroller is connected to a first terminal of the first switch via a first resistor,
wherein a second input of the microcontroller is connected to a second terminal of the first switch via a second resistor,
wherein there is no current flow between the first terminal of the first switch and the second terminal of the first switch when the first switch is open, and
wherein the microcontroller is configured to detect voltage at the first and second inputs when the first and second switches are closed and to take them into account as part of the test routine.

2. The apparatus of claim 1, wherein the first input of the microcontroller is connected to ground via a third resistor, and wherein the second input of the microcontroller is connected to ground via a fourth resistor.

3. The apparatus of claim 1, wherein the first input of the microcontroller is provided with a first analog-to-digital converter, and wherein the second input of the microcontroller is provided with a second analog-to-digital converter.

4. The apparatus of claim 1, wherein the first input of the microcontroller is connected to the first terminal of the first switch via a first analog-to-digital converter and the first resistor, and wherein the second input of the microcontroller is connected to the second terminal of the first switch via a second analog-to-digital converter and the second resistor.

5. The apparatus of claim 1, wherein the second input of the microcontroller is connected to a first terminal of the second switch via the second resistor.

6. The apparatus of claim 5, wherein the test routine comprises opening the second switch and monitoring a voltage drop at the second input and opening the first switch and monitoring a voltage drop at the first input.

7. The apparatus of claim 1, wherein the taking into account as part of the test routine comprises shifting a target voltage range with respect to a voltage difference between the first input and the second input or correcting the voltage difference based on the detected voltages.

8. The apparatus of claim 6, wherein a third input of the microcontroller is connected to a second terminal of the second switch via a third resistor.

9. The apparatus of claim 8, wherein the microcontroller is configured to detect the voltage at the third input when the first and second switches are closed and to take it into account as part of the test routine.

10. The apparatus of claim 9, wherein the third input of the microcontroller is provided with a third analog-to-digital converter.

11. The apparatus of claim 1, wherein the first switch is a first semiconductor switch controlled by the microcontroller, and wherein the second switch is a second semiconductor switch controlled by the microcontroller.
